(19) United States
(12) Patent Application Publication
(10) Pub. No.: US 2025/0157686 A1
(43) Pub. Date: May 15, 2025

(54) REFLECTOR FOR GENERATING NEUTRAL BEAMS AND SUBSTRATE PROCESSING APPARATUS INCLUDING THE SAME

(71) Applicant: SAMSUNG ELECTRONICS CO., LTD., SUWON-SI (KR)

(72) Inventors: Younseon WANG, Suwon-si (KR); Siyoung KOH, Suwon-si (KR); Bonseung GOO, Suwon-si (KR); Junho IM, Suwon-si (KR); Dongwan KIM, Suwon-si (KR); Minsung KIM, Suwon-si (KR); Jisoo IM, Suwon-si (KR)

(21) Appl. No.: 18/810,735

(22) Filed: Aug. 21, 2024

(30) Foreign Application Priority Data
Nov. 14, 2023 (KR) 10-2023-0157691

(51) Int. Cl. G21K 1/06

(52) U.S. Cl. CPC G21K 1/06

(57) ABSTRACT

A reflector for generating neutral beams, the reflector includes a plurality of reflective plates Ion beams from an ion source collide against each of the plurality of reflective plates. The plurality of reflective plates reflect the ion beams and convert the ion beams into neutral beams. A coupling portion disposed between the plurality of reflective plates. Each of the plurality of reflective plates comprises a first surface, a second surface disposed on a first end of the first surface, and a third surface disposed on a second end of the first surface that is opposite to the first end.

### CROSS-REFERENCE TO RELATED APPLICATION

This application claims priority under 35 U.S.C. § 119 to Korean Patent Application No. 10-2023-0157691, filed on Nov. 14, 2023 in the Korean Intellectual Property Office, the disclosure of which is incorporated by reference in its entirety herein.

### 1. TECHNICAL FIELD

The present inventive concept relates to a reflector for generating neutral beams and a substrate processing apparatus including the same.

### 2. DISCUSSION OF RELATED ART

Along with the refinement of semiconductors, there has been an increased demand for a low-pollution manufacturing process. The influence of particles due to the generation of dust in semiconductor manufacturing equipment, such as plasma equipment, may be severe. The plasma equipment includes, for example, dry etching equipment, plasma chemical vapor deposition (CVD) equipment, or the like. Particles may be generated when halogen-based etching gas or material gas corrodes the inner wall or internal components of a chamber. Accordingly, corrosion resistance is required for members used in semiconductor manufacturing equipment including plasma equipment.

### SUMMARY

Embodiments of the present inventive concept provides a reflector for generating neutral beams, capable of increasing the process yield of etching equipment and reducing process defects, and a substrate processing apparatus including the same.

According to an embodiment of the present inventive concept, a reflector for generating neutral beams includes a plurality of reflective plates. Ion beams from an ion source collide against each of the plurality of reflective plates. The plurality of reflective plates reflect the ion beams and convert the ion beams into neutral beams. A coupling portion disposed between the plurality of reflective plates. Each of the plurality of reflective plates comprises a first surface, a second surface disposed on a first end of the first surface, and a third surface disposed on a second end of the first surface that is opposite to the first end.

According to an embodiment of the present inventive concept, a reflector for generating neutral beams includes a plurality of reflective plates. Ion beams from an ion source collide against each of the plurality of reflective plates. The plurality of reflective plates reflect the ion beams and convert the ion beams into neutral beams. A coupling portion is disposed between the plurality of reflective plates. Each of the plurality of reflective plates comprises a first surface, a second surface disposed on a first end of the first surface, and a third surface disposed on a second end of the first surface that is opposite to the first end. The coupling portion is disposed on the second and third surfaces of each of the plurality of reflective plates. The coupling portion has a ring structure as a whole.

According to an embodiment of the present inventive concept, a substrate processing apparatus includes an ion source generating ion beams. A reflector generates neutral beams. The reflector is disposed on a traveling path of the ion beams. The reflector reflects the ion beams and converts the ion beams into neutral beams. A substrate support is disposed on a traveling path of the neutral beams. The reflector includes a plurality of reflective plates. The ion beams from the ion source collide against each of the plurality of reflective plates. A coupling portion is disposed between the plurality of reflective plates. Each of the plurality of reflective plates comprises a first surface, a second surface disposed on a first end of the first surface, and a third surface disposed on a second end of the first surface that is opposite to the first end.

### BRIEF DESCRIPTION OF THE DRAWINGS

Non-limiting embodiments of the present inventive concept will be more clearly understood from the following detailed description taken in conjunction with the accompanying drawings in which:

FIG. 1 is a schematic diagram illustrating a substrate processing apparatus according to an embodiment of the present inventive concept;

FIG. 2 is a perspective view of a reflector according to an embodiment of the present inventive concept;

FIG. 3 is a magnified cross-sectional view of a reflective plate shown in FIG. 2 according to an embodiment of the present inventive concept;

FIG. 4 is a cross-sectional view showing a reflective plate and a coupling portion according to an embodiment of the present inventive concept;

FIGS. 5A and 5B are cross-sectional views showing a reflective plate and a coupling portion according to embodiments of the present inventive concept;

FIGS. 6A and 6B are cross-sectional views showing a reflective plate and a coupling portion according to embodiments of the present inventive concept;

FIG. 7 is a cross-sectional view illustrating etching equipment having a reflector according to an embodiment of the present inventive concept;

FIG. 8 is a flowchart illustrating a method of manufacturing a reflector, according to an embodiment of the present inventive concept; and

FIG. 9 is a flowchart illustrating a method of manufacturing a reflector, according to an embodiment of the present inventive concept.

### DETAILED DESCRIPTION OF EMBODIMENTS

Hereinafter, a reflector for generating neutral beams and a substrate processing apparatus including the same are described in detail with reference to the accompanying drawings. The embodiments described below are only illustrative, and various changes in form and details may be made therein. Like reference numerals in the drawings denote like elements, and the sizes of components in the drawings may be exaggerated for convenience and clarity of description.

Hereinafter, the expression “above” or “on” may include not only directly on/beneath/left/right in a contact manner but also above/under/left/right in a contactless manner. For example, unless otherwise specified, intervening elements may be present.

Though terms like ‘first’ and ‘second’ are used to describe various elements, these terms are used only to differentiate an element from another element. These terms do not limit the difference in materials or structures of elements.

An expression in the singular includes an expression in the plural unless they are clearly different from each other in context. In addition, when a component “includes” an element, unless there is another opposite description thereto, it should be understood that the component does not exclude another element but may further include such additional element.

In addition, terms such as “ . . . unit”, “ . . . module”, and the like refer to units that perform at least one function or operation, and the units may be implemented as hardware, software, or a combination of hardware and software.

For steps forming a method, if an order is not clearly disclosed or, if there is no disclosure opposed to the clear order, the steps can be performed in any order deemed proper. In addition, the use of all illustrations or illustrative terms (for example, etc.) is simply to describe the technical idea in detail, and the scope of embodiments of the present inventive concept are not limited due to the illustrations or illustrative terms.

Hereinafter, embodiments of the present inventive concept are described in detail with reference to the accompanying drawings. However, the present inventive concept may be embodied in many different forms and should not be construed as being limited to the embodiments set forth herein. Rather, the described embodiments are provided so that this disclosure will be thorough and complete, and will convey the present inventive concept to those of ordinary skill in the art. In the drawings, the thicknesses of layers and regions are exaggerated for clarity. Like reference numerals denote like elements throughout the specification.

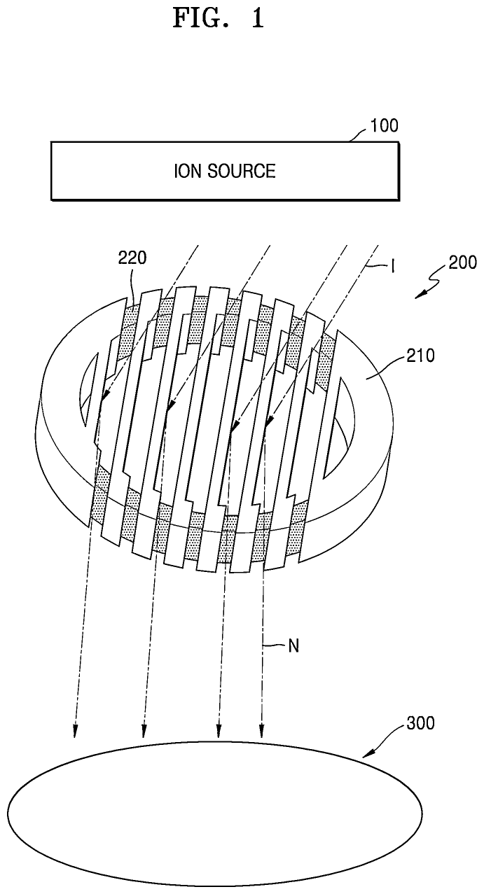

FIG. 1 is a schematic diagram illustrating a substrate processing apparatus according to an embodiment.

Referring to FIG. 1, a reflector 200 may be disposed on a traveling path of ion beams I provided from an ion source 100. The ion beams I provided from the ion source 100 are incident on the reflector 200. In an embodiment, the ion source 100 may include a plasma generator and a grid unit configured to extract and accelerate ions from the plasma generator. In an embodiment, the reflector 200 may include reflective plates 210 arranged in parallel to each other to have a certain angle with respect to the ion beams I. According to an embodiment, the reflector 200 may include the reflective plates 210 and coupling portions 220, which are in direct contact with each other. The coupling portions 220 are disposed between the reflective plates 210 and may couple the reflective plates 210 to each other. The reflective plates 210 are described below in detail. The ion beams I may be converted into neutral beams N by losing or gaining charges through collision with the reflective plates 210. A substrate support 300 fixing a substrate to be processed may be disposed on a traveling path of the neutral beams N, thereby performing processing, such as etching, by the neutral beams N.

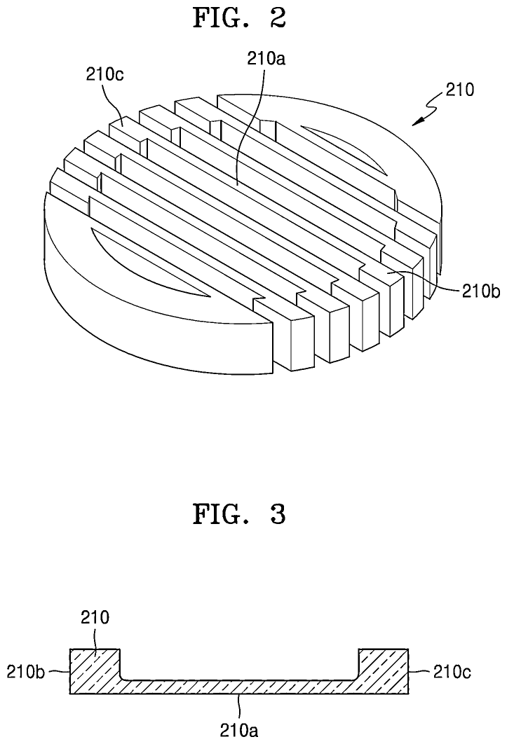

FIG. 2 is a perspective view of a plurality of reflective plates 210 according to an embodiment, and FIG. 3 is a magnified cross-sectional view of a reflective plate 210 shown in FIG. 2.

Referring to FIGS. 2 and 3, each of the plurality of reflective plates 210 may include a first surface 210a, a second surface 210b provided on a first end of the first surface 210a, and a third surface 210c provided on an opposite second end of the first surface 210a. In an embodiment, the first surface 210a may have a constant thickness. The second surface 210b may have a constant thickness. The third surface 210c may have a constant thickness. The thickness may be a length in a horizontal direction parallel to an upper surface of the reflective plate 210. In an embodiment, the thickness of the first surface 210a may be less than the thickness of the second surface 210b or the third surface 210c. In an embodiment, the first surface 210a may be flat. The plurality of reflective plates 210 may be spaced apart from each other at certain intervals such that the first surfaces 210a of the plurality of reflective plates 210 are arranged parallel to each other. Each of the second surface 210b and the third surface 210c may have a certain angle with respect to the first surface 210a. Each of the second surfaces 210b and the third surfaces 210c of the plurality of reflective plates 210 may include a curved surface to form a ring structure as a whole. In an embodiment, the coupling portions 220 may be disposed solely on the second and third surfaces 210b, 210c of the plurality of reflective plates 210 and may have a ring structure as a whole.

In general, a material used for a reflector for generating neutral beams should have low surface roughness for an incident surface against which ion beams collide for uniform angle distribution of neutral beams reflected from a reflective plate and have high electrical conductivity for high neutralization efficiency. In addition, the material used for a reflector for generating neutral beams should have low chemical reactivity and low sputtering yield to prevent surface deformation of an incident surface and prevent contamination of a substrate to be processed. Furthermore, the material used for a reflector for generating neutral beams should have high thermal conductivity and a low thermal expansion coefficient to prevent thermal deformation due to collision with ion beams. However, it may be difficult for an existing reflective plate made of a single metal material to satisfy all the characteristics described above.

The reflective plate 210 may include a material having low surface roughness, high electrical conductivity, low chemical reactivity, and low sputtering yield. In an embodiment, the reflective plate 210 may include an alloy and ceramic. For example, the reflective plate 210 may include aluminum, stainless steel, a nickel iron alloy, a nickel chromium alloy, a nickel iron chromium alloy, polysilicon, silicon (Si), silicon carbide (SiC), or graphite. However, the reflective plate 210 is not necessarily limited thereto. For example, ceramic, a metal, and an alloy satisfying the conditions described above may be applied to the reflective plate 210 without limitation.

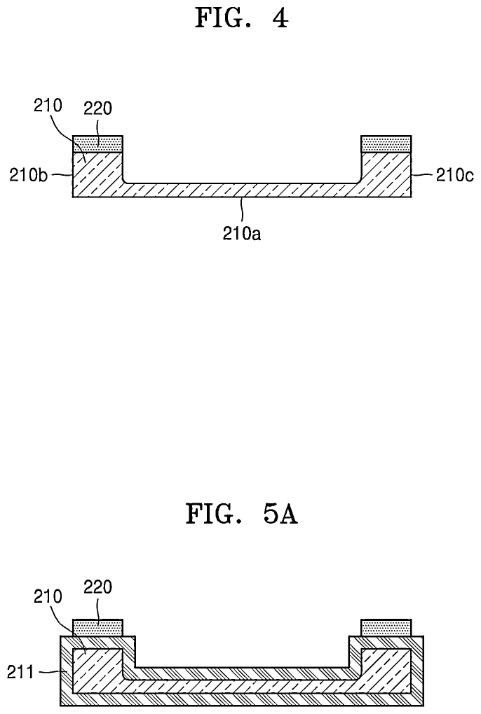

FIG. 4 is a cross-sectional view showing the reflective plate 210 and a coupling portion 220 according to an embodiment.

Referring to FIG. 4, the coupling portion 220 may be provided on (e.g., disposed directly thereon) the second surface 210b and the third surface 210c of the reflective plate 210. In an embodiment, the width (e.g., length in a horizontal direction) of the coupling portion 220 may be less than the width (e.g., length in a horizontal direction) of the second surface 210b or the third surface 210c. For convenience, although only one reflective plate 210 is shown in FIG. 4, as shown in FIG. 1, the coupling portion 220 may be provided between the plurality of reflective plates 210 to connect the plurality of reflective plates 210 to each other. In an embodiment, the coupling portion 220 may include an active metal binder. For example, in an embodiment the coupling portion 220 may include any one of titanium (Ti), silver (Ag), and a combination thereof. The coupling portion 220 may include any one of silver copper titanium (AgCuTi, TiCuSil), a copper active brazing alloy (Cu ABA), silver copper tin titanium (AgCuSnTi), and a combination thereof. However, embodiments of the present disclosure are not necessarily limited thereto, and various materials having excellent thermal stability to prevent thermal deformation of the reflective plate 210 may be used. In addition, the reflective plate 210 and the coupling portion 220 may have the same thermal expansion coefficient to prevent thermal deformation due to a thermal expansion coefficient difference.

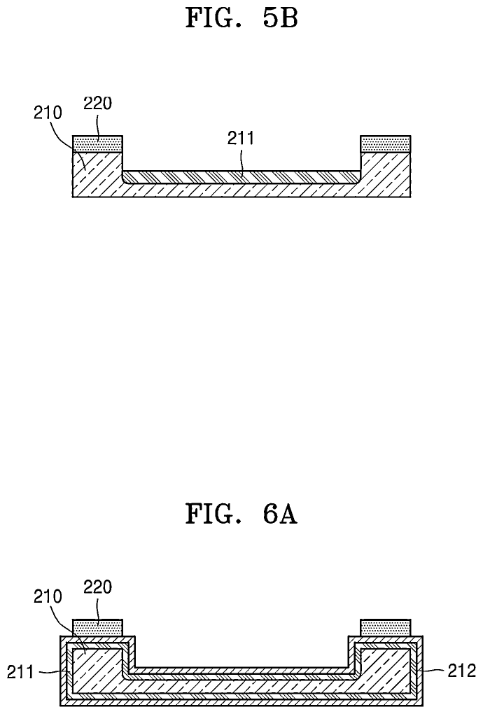

FIGS. 5A and 5B are cross-sectional views showing the reflective plate 210 and the coupling portion 220 according to embodiments of the present disclosure.

Referring to FIG. 5A, a coating layer 211 may be additionally provided on (e.g., disposed directly thereon) the reflective plate 210. In an embodiment, the coating layer 211 may be provided on (e.g., disposed directly thereon) the whole surface (e.g., an entirety of the exposed surface) of the reflective plate 210. Alternatively, as shown in FIG. 5B, the coating layer 211 may be provided on (e.g., disposed directly thereon) a partial surface of the reflective plate 210, such as on an entirety of the upper surface of the first surface 210a and a partial portion of the sidewalls of the second surface 210b and third surface 210c. In an embodiment, the coating layer 211 may be provided on a portion to be neutralized due to collision with ion beams. The reflective plate 210, the coating layer 211, and the coupling portion 220 may be sequentially stacked. In an embodiment, the coating layer 211 may include any one of molybdenum (Mo), tungsten (W), titanium (Ti), nickel (Ni), Si, SiC, and a combination thereof. In an embodiment, the coating layer 211 may be provided on the surface of the reflective plate 210 by a corrosion-resistant coating method (e.g., aerosol deposition (AD), physical vapor deposition (PVD), chemical vapor deposition (CVD), or atomic layer deposition (ALD)). While each reflective plate 210 is separated, coating may be performed by AD, PVD, CVD, or ALD. While each reflective plate 210 is separated, the coating layer 211 may be coated on the reflective plate 210 by AD, PVD, CVD, or ALD such that the coating layer 211 is formed to be relatively thin. For example, in an embodiment the thickness of the coating layer 211 may be in a range of about 1 μm to about 50 μm. While each reflective plate 210 is separated, the coating layer 211 may be coated on the reflective plate 210 by AD, PVD, CVD, or ALD such that the porosity of the coating layer 211 is relatively low. For example, the porosity of the coating layer 211 may be in a range of about 0.01% to about 1%. In an embodiment, the reflector 200 may be formed by providing the coupling portion 220 to the reflective plate 210 to which coating has been applied. While each reflective plate 210 is separated, the coating layer 211 may be coated on the reflective plate 210 by AD, PVD, CVD, or ALD such that the surface roughness of the reflector 200 is relatively low. For example, the surface roughness Ra of the reflector 200 may be in a range of about 0.001 μm to about 0.1 μm.

In an embodiment, the coupling portion 220 may include a metal having a melting point lower than that of the coating layer 211. The coupling portion 220 may include an active metal binder. For example, in an embodiment the coupling portion 220 may include any one of Ti, Ag, and a combination thereof. The coupling portion 220 may include any one of AgCuTi, TiCuSil, a Cu ABA, AgCuSnTi, and a combination thereof.

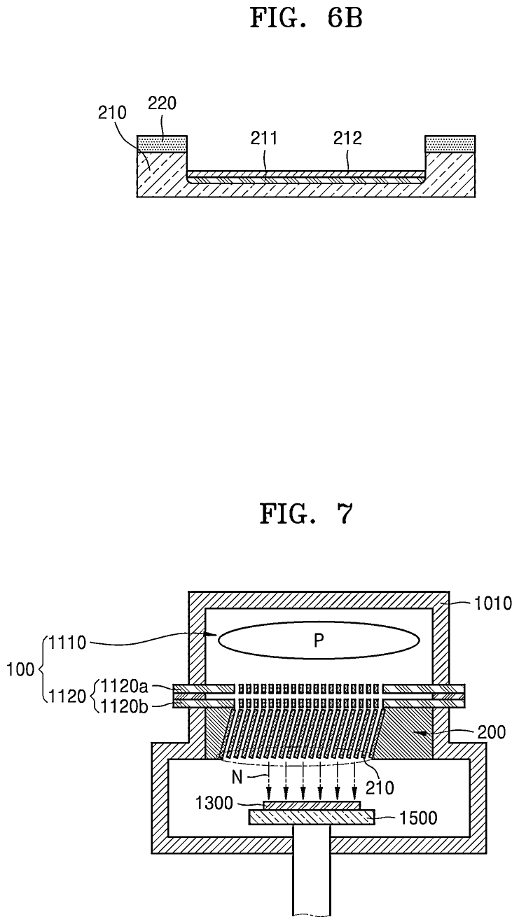

FIGS. 6A and 6B are cross-sectional views showing the reflective plate 210 and the coupling portion 220 according to embodiments. Differences from the embodiments of FIGS. 5A and 5B are mainly described and a repeated description of similar or identical elements may be omitted for economy of description.

Referring to FIG. 6A, a plurality of coating layers 211 and 212 may be provided on the reflective plate 210. For convenience, the coating layer 211 is also referred to as a first coating layer and the coating layer 212 is also referred to as a second coating layer. The first coating layer 211 may be provided on the whole surface (e.g., disposed on an entirety of the exposed surface) of the reflective plate 210, and the second coating layer 212 may be provided on the whole surface (e.g., disposed on an entirety of the exposed surface) of the first coating layer 211. Alternatively, as shown in FIG. 6B, the first coating layer 211 may be provided on a partial surface of the reflective plate 210, and the second coating layer 212 may be provided on the whole surface (e.g., disposed on an entirety of the exposed surface) of the first coating layer 211. Alternatively, the first coating layer 211 may be provided on a partial surface of the reflective plate 210, and the second coating layer 212 may be provided on a partial surface of the first coating layer 211. The first and second coating layers 211 and 212 may be provided on a portion to be neutralized due to collision with ion beams. In an embodiment, the second coating layer 212 may include any one of Mo, W, Ti, Ni, Si, SiC, and a combination thereof. The reflective plate 210, the first and second coating layers 211 and 212, and the coupling portion 220 may be sequentially stacked. In an embodiment, the second coating layer 212 may be provided on the surface of the first coating layer 211 by AD, PVD, CVD, or ALD. While each reflective plate 210 is separated, the first coating layer 211 may be coated on each reflective plate 210 by AD, PVD, CVD, or ALD. While each reflective plate 210 is separated, the second coating layer 212 may be coated on the first coating layer 211 by AD, PVD, CVD, or ALD such that the second coating layer 212 is relatively thin. For example, in an embodiment the thickness of the second coating layer 212 may be in a range of about 0.2 μm to about 50 μm. Alternatively, the thickness of the first coating layer 211 may be in a range of about 0.2 μm to about 25 μm inclusive, and the thickness of the second coating layer 212 may be in a range of about 0.2 μm to about 25 μm inclusive. While each reflective plate 210 is separated, the second coating layer 212 may be coated on the first coating layer 211 by AD, PVD, CVD, or ALD such that the porosity of the second coating layer 212 is relatively low. For example, in an embodiment the porosity of the second coating layer 212 may be in a range of about 0.01% to about 1%. The reflector 200 may be formed by providing the coupling portion 220 to the reflective plate 210 to which the plurality of coating layers 211 and 212 have been applied. While each reflective plate 210 is separated, the plurality of coating layers 211 and 212 may be coated on the reflective plate 210 by AD, PVD, CVD, or ALD such that the surface roughness of the reflector 200 is relatively low. For example, in an embodiment the surface roughness Ra of the reflector 200 may be in a range of about 0.001 μm to about 0.1 μm.

Although only two coating layers 211 and 212 are shown in FIGS. 6A and 6B, embodiments of the present disclosure are not necessarily limited thereto. For example, in some embodiments three or more coating layers may be provided (e.g., consecutively stacked) on the reflective plate 210.

FIG. 7 is a cross-sectional view illustrating etching equipment having the reflector 200 according to an embodiment.

Referring to FIG. 7, the ion source 100 is provided to an upper region of a chamber 1010. In an embodiment, the ion source 100 may include a plasma generator 1110 and a grid unit 1120 provided under the plasma generator 1110. The plasma generator 1110 may generate plasma P from various kinds of reaction gas. In an embodiment, the plasma generator 1110 may employ inductively coupled plasma (ICP) for generating plasma by applying induced power to an induction coil, or capacitively coupled plasma (CCP). Furthermore, the plasma generator 1110 may employ electron cyclotron resonance (ECR) plasma or helicon plasma.

In an embodiment, the grid unit 1120 may include a first grid 1120a and a second grid 1120b respectively having first through holes and second through holes that communicate with each other. In an embodiment, different magnitudes of voltages are applied to the first grid 1120a and the second grid 1120b, respectively, and in this embodiment, ions in the plasma P are extracted and accelerated through the through holes due to the potential difference between the voltages. In an embodiment, a third grid may be additionally provided beneath the second grid 1120b. The third grid may maintain the directivity of the extracted ions to be sufficient. In an embodiment, the third grid may be grounded.

The reflector 200 may be provided beneath the grid unit 1120. In an embodiment, the reflector 200 may include the plurality of reflective plates 210 as described above. The plurality of reflective plates 210 may be arranged to be parallel to each other such that the plurality of reflective plates 210 have a certain angle with respect to a traveling path of ion beams including ions extracted through the grid unit 1120. The ion beams incident to the reflector 200 may be converted into neutral beams N by obtaining or losing charges while colliding with the plurality of reflective plates 210 and incident to a substrate 1300 to be processed. In this embodiment, the neutral beams N may be vertically incident (e.g., substantially perpendicular) to the substrate 1300 to be processed. The substrate 1300 to be processed may be fixed onto a substrate support 1500 arranged in a lower region of the chamber 1010. In addition, a particular material layer to be etched may be previously formed on the substrate 1300 to be processed.

As described above, the etching equipment according to an embodiment may include the reflector 200 for generating neutral beams. A description of the reflector 200 has been made in detail with reference to FIGS. 1 to 6B and is thus omitted hereinafter. The reflector 200 may have a relatively low surface roughness and increased thermal stability, thereby increasing the process yield of the etching equipment and reducing process defects.

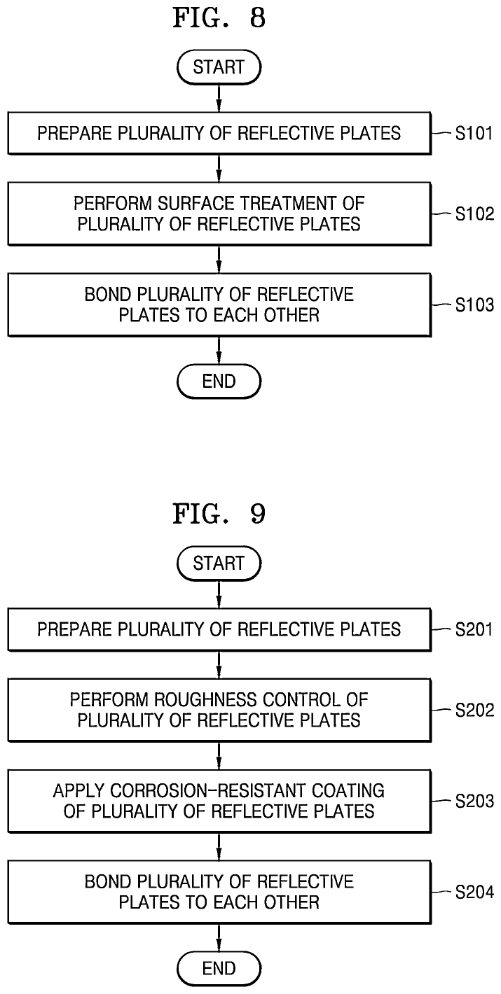

FIG. 8 is a flowchart illustrating a method of manufacturing a reflector, according to an embodiment.

Referring to FIG. 8, first, the plurality of reflective plates 210 may be prepared in block S101. In an embodiment, the plurality of reflective plates 210 may be spaced apart from each other at certain intervals such that the plurality of reflective plates 210 are arranged parallel to each other. In an embodiment, the reflective plate 210 may include a material having a relatively low surface roughness, relatively high electrical conductivity, relatively low chemical reactivity, and relatively low sputtering yield. The reflective plate 210 may include an alloy. For example, in an embodiment the reflective plate 210 may include stainless steel, a nickel iron alloy, a nickel chromium alloy, or a nickel iron chromium alloy. However, embodiments of the present disclosure are not necessarily limited thereto. For example, in an embodiment the reflective plate 210 may include a metal and an alloy satisfying the conditions described above.

After preparing the plurality of reflective plates 210, surface treatment of the plurality of reflective plates 210 may be performed in block S102. Herein, roughness control and corrosion-resistant coating of the plurality of reflective plates 210 may be performed. In an embodiment, the corrosion-resistant coating may be performed by AD, PVD, CVD, or ALD.

After performing the surface treatment of the plurality of reflective plates 210, the plurality of reflective plates 210 may be bonded to each other in block S103. The coupling portion 220 may be provided between the plurality of reflective plates 210 to connect the plurality of reflective plates 210 to each other. The coupling portion 220 may include an active metal binder. For example, in an embodiment the coupling portion 220 may include any one of Ti, Ag, and a combination thereof. The coupling portion 220 may include any one of AgCuTi, TiCuSil, a Cu ABA, AgCuSnTi, and a combination thereof. However, embodiments of the present disclosure are not necessarily limited thereto and the coupling portion 220 may include other materials having excellent thermal stability to prevent thermal deformation of the reflective plate 210. In addition, in an embodiment the reflective plate 210 and the coupling portion 220 may have the same thermal expansion coefficient to prevent thermal deformation due to a thermal expansion coefficient difference.

FIG. 9 is a flowchart illustrating a method of manufacturing a reflector, according to an embodiment.

Referring to FIG. 9, a plurality of reflective plates 210 may be prepared in block S201. Block S201 of FIG. 9 of preparing the plurality of reflective plates 210 may be similar to block S101 of FIG. 8 of preparing the plurality of reflective plates 210.

After preparing the plurality of reflective plates 210, the roughness control of the plurality of reflective plates 210 may be performed in block S202. After performing the roughness control of the plurality of reflective plates 210, corrosion-resistant coating may be applied to the plurality of reflective plates 210 in block S203. In an embodiment, a coating layer 211 may be formed on the plurality of reflective plates 210 by performing coating by PVD, CVD, or ALD. In an embodiment, the coating layer 211 may be provided on the whole surface (e.g., an entirety of the exposed surface) of the reflective plate 210. Alternatively, the coating layer 211 may be provided on a partial surface of the reflective plate 210. The reflective plate 210, the coating layer 211, and the coupling portion 220 may be sequentially stacked. In an embodiment, the coating layer 211 may include any one of Mo, W, Ti, Ni, Si, SiC, and a combination thereof. The coating layer 211 may be provided on the surface of the reflective plate 210 by AD, PVD, CVD, or ALD. While each reflective plate 210 is separated, coating may be performed by AD, PVD, CVD, or ALD. While each reflective plate 210 is separated, the coating layer 211 may be coated on the reflective plate 210 by AD, PVD, CVD, or ALD such that the coating layer 211 is formed to be relatively thin. For example, in an embodiment the thickness of the coating layer 211 may be in a range of about 0.2 μm to about 50 μm. While each reflective plate 210 is separated, the coating layer 211 may be coated on the reflective plate 210 by AD, PVD, CVD, or ALD such that the porosity of the coating layer 211 is relatively low. For example, the porosity of the coating layer 211 may be in a range of 0.01% to 1%. The reflector 200 may be formed by providing the coupling portion 220 to the reflective plate 210 to which coating has been applied. While each reflective plate 210 is separated, the coating layer 211 may be coated on the reflective plate 210 by AD, PVD, CVD, or ALD such that the surface roughness of the reflector 200 is relatively low. For example, in an embodiment the surface roughness Ra of the reflector 200 may be in a range of about 0.001 μm to about 0.1 μm.

The coupling portion 220 may include a metal having a melting point lower than that of the coating layer 211. The coupling portion 220 may include an active metal binder. For example, in an embodiment the coupling portion 220 may include any one of titanium Ti, Ag, and a combination thereof. The coupling portion 220 may include any one of AgCuTi, TiCuSil, a Cu ABA, AgCuSnTi, and a combination thereof.

The plurality of coating layers 211 and 212 may be provided on the reflective plate 210. For convenience, the coating layer 211 is also referred to as a first coating layer 211 and the coating layer 212 is also referred to as a second coating layer. In an embodiment, the first coating layer 211 may be provided on the whole surface (e.g., an entirety of the exposed surface) of the reflective plate 210, and the second coating layer 212 may be provided on the whole surface of the first coating layer 211. Alternatively, the first coating layer 211 may be provided on a partial surface of the reflective plate 210, and the second coating layer 212 may be provided on the whole surface (e.g., an entirety of the exposed surface) of the first coating layer 211. Alternatively, the first coating layer 211 may be provided on a partial surface of the reflective plate 210, and the second coating layer 212 may be provided on a partial surface of the first coating layer 211. In an embodiment, the second coating layer 212 may include any one of Mo, Kovar, W, Ti, Ni, Si, SiC, and a combination thereof. The reflective plate 210, the coating layer 211, and the coupling portion 220 may be sequentially stacked. In an embodiment, the second coating layer 212 may be provided on the surface of the first coating layer 211 by AD, PVD, CVD, or ALD. While each reflective plate 210 is separated, the first coating layer 211 may be coated on each reflective plate 210 by AD, PVD, CVD, or ALD. While each reflective plate 210 is separated, the second coating layer 212 may be coated on the first coating layer 211 by AD, PVD, CVD, or ALD such that the second coating layer 212 is thin. For example, in an embodiment the thickness of the second coating layer 212 may be in a range of about 0.2 μm to about 50 μm. Alternatively, the thickness of the first coating layer 211 may be in a range of about 0.2 μm to about 25 μm, and the thickness of the second coating layer 212 may be in a range of about 0.2 μm to about 25 μm. While each reflective plate 210 is separated, the second coating layer 212 may be coated on the first coating layer 211 by AD, PVD, CVD, or ALD such that the porosity of the second coating layer 212 is relatively low. For example, the porosity of the second coating layer 212 may be in a range of about 0.01% to about 1%. The reflector 200 may be formed by providing the coupling portion 220 to the reflective plate 210 to which the plurality of coating layers 211 and 212 have been applied. While each reflective plate 210 is separated, the plurality of coating layers 211 and 212 may be coated on the reflective plate 210 by AD, PVD, CVD, or ALD such that the surface roughness of the reflector 200 is relatively low. For example, the surface roughness Ra of the reflector 200 may be in a range of about 0.001 μm to about 0.1 μm. Alternatively, in an embodiment three or more coating layers may be provided on the reflective plate 210.

After forming the coating layer 211 on the plurality of reflective plates 210, the plurality of reflective plates 210 may be bonded to each other in block S204. Block S204 of FIG. 9 of bonding the plurality of reflective plates 210 to each other may be similar to block S103 of FIG. 8 of bonding the plurality of reflective plates 210 to each other.

The reflector 200 manufactured by the reflector manufacturing method of FIG. 8 or 9 described above may have relatively low surface roughness and increased thermal stability, thereby increasing the process yield of a substrate processing apparatus and reducing process defects.

While the present inventive concept has been particularly shown and described with reference to non-limiting embodiments thereof, it will be understood that various changes in form and details may be made therein without departing from the spirit and scope of the present inventive concept.

What is claimed is:

1. A reflector for generating neutral beams, the reflector comprising:
a plurality of reflective plates, wherein ion beams from an ion source collide against each of the plurality of reflective plates, the plurality of reflective plates reflecting the ion beams and converting the ion beams into neutral beams; and
a coupling portion disposed between the plurality of reflective plates,
wherein each of the plurality of reflective plates comprises a first surface, a second surface disposed on a first end of the first surface, and a third surface disposed on a second end of the first surface that is opposite to the first end.

2. The reflector of claim 1, wherein a plurality of coating layers are disposed on each of the plurality of reflective plates.

3. The reflector of claim 1, wherein:
a coating layer is disposed on each of the plurality of reflective plates, the coating layer including at least one compound selected from molybdenum (Mo), tungsten (W), titanium (Ti), nickel (Ni), silicon (Si) and silicon carbide (SiC).

4. The reflector of claim 1, wherein:
a coating layer is disposed on each of the plurality of reflective plates; and
the coupling portion includes a metal having a melting point lower than a melting point of the coating layer.

5. The reflector of claim 1, wherein the coupling portion includes an active metal binder.

6. The reflector of claim 1, wherein the coupling portion includes at least one compound selected from titanium (Ti) and silver (Ag).

7. The reflector of claim 1, wherein the coupling portion includes at least one material selected from silver copper titanium (AgCuTi, TiCuSil), a copper active brazing alloy (Cu ABA) and silver copper tin titanium (AgCuSnTi).

8. The reflector of claim 1, wherein:
a coating layer is disposed on each of the plurality of reflective plates; and
a thickness of the coating layer is in a range of about 0.2 μm to about 50 μm.

9. The reflector of claim 1, wherein a porosity of the plurality of reflective plates is in a range of about 0.01% to about 1%.

10. The reflector of claim 1, wherein a surface roughness of the plurality of reflective plates is in a range of about 0.001 μm to about 0.1 μm.

11. The reflector of claim 1, wherein the plurality of reflective plates has a substantially same thermal expansion coefficient as a thermal expansion coefficient of the coupling portion.

12. A reflector for generating neutral beams, the reflector comprising:
a plurality of reflective plates, wherein ion beams from an ion source collide against each of the plurality of reflective plates, the plurality of reflective plates reflecting the ion beams and converting the ion beams into neutral beams; and
a coupling portion disposed between the plurality of reflective plates,
wherein each of the plurality of reflective plates comprises a first surface, a second surface disposed on a first end of the first surface, and a third surface disposed on a second end of the first surface that is opposite to the first end, the coupling portion is disposed on the second and third surfaces of each of the plurality of reflective plates, the coupling portion has a ring structure as a whole.

13. The reflector of claim 12, wherein a plurality of coating layers are disposed on each of the plurality of reflective plates.

14. The reflector of claim 12, wherein a coating layer is disposed on each of the plurality of reflective plates, the coupling portion includes a metal having a melting point lower than a melting point of the coating layer.

15. The reflector of claim 12, wherein the coupling portion includes at least one compound selected from titanium (Ti) and silver (Ag).

16. The reflector of claim 12, wherein the coupling portion includes at least one material selected from silver copper titanium (AgCuTi, TiCuSil), a copper active brazing alloy (Cu ABA) and a silver copper tin titanium (AgCuSnTi).

17. The reflector of claim 12, wherein:
a coating layer is disposed on each of the plurality of reflective plates; and
a thickness of the coating layer is in a range of about 0.2 μm to about 50 μm.

18. The reflector of claim 12, wherein a porosity of the plurality of reflective plates is in a range of about 0.01% to about 1%.

19. The reflector of claim 12, wherein a surface roughness of the plurality of reflective plates is in a range of about 0.001 μm to about 0.1 μm.

20. A reflector for generating neutral beams, the reflector comprising:
a plurality of reflective plates, wherein the ion beams from the ion source collide against each of the plurality of reflective plates; and
a coupling portion disposed between the plurality of reflective plates, and
wherein each of the plurality of reflective plates comprises a first surface, a second surface disposed on a first end of the first surface, and a third surface disposed on a second end of the first surface that is opposite to the first end, the coupling portion is disposed on the second and third surfaces of each of the plurality of reflective plates, the coupling portion has a ring structure as a whole, and a coating layer is disposed on the first surface of each of the plurality of reflective plates.
